(19) United States
(12) Patent Application Publication
(10) Pub. No.: US 2026/0070758 A1
(43) Pub. Date: Mar. 12, 2026

(54) ELEVATOR INFORMATION PROVIDING DEVICE, ELEVATOR INFORMATION PROVIDING METHOD, AND LEARNING DEVICE

(71) Applicant: Mitsubishi Electric Corporation, Tokyo (JP)

(72) Inventors: Reiko SAKATA, Tokyo (JP); Saki MATSUI, Tokyo (JP); Ryuta ENDO, Tokyo (JP)

(73) Assignee: Mitsubishi Electric Corporation, Tokyo (JP)

(21) Appl. No.: 19/351,337

(22) Filed: Oct. 7, 2025

Related U.S. Application Data
(63) Continuation of application No. PCT/JP2023/015334, filed on Apr. 17, 2023.

(51) Int. Cl. B66B 19/00; G06F 30/27

(52) U.S. Cl. CPC B66B 19/00; G06F 30/27

(57) ABSTRACT

The objective is to obtain an elevator information providing device that enables a user of the elevator information providing device to examine the specification of an elevator on the basis of a standard model. The elevator information providing device includes: a building data acquiring unit that acquires data of a building; and an inference unit that infers a standard model of an elevator from the data of the building input from the building data acquiring unit and output data of the inferred standard model of the elevator, using a trained model for inferring the standard model of the elevator suitable for installation in the building from the data of the building.

### CROSS-REFERENCE TO RELATED APPLICATION

This disclosure is a continuation of International Patent Application No. PCT/JP2023/015334, filed on Apr. 17, 2023, the entire contents of which are incorporated herein by reference.

### TECHNICAL FIELD

The present invention relates to an elevator information providing device, an elevator information providing method, and a learning device.

### BACKGROUND ART

An architectural designer on the elevator ordering side orders an elevator that meets his/her request, using an elevator information providing device.

The architectural designer inputs the purpose of use of the building, the number of floors of the building, an estimated resident population per floor, and the required specification for an elevator to the elevator information providing device, and then orders an elevator. (Patent Literature 1, for example)

### CITATION LIST

### Patent Literature

Patent Literature 1: JP 2002-230253 A

### SUMMARY OF INVENTION

### Technical Problem

With such an elevator information providing device, the user of the elevator information providing device is not able to examine the specification of an elevator on the basis of a standard model. The manufacturer on the elevator manufacturing side preferably guides the user of the elevator information providing device to examination of the specification of an elevator on the basis of a standard model, with the load during the manufacturing process and the like being taken into consideration.

The present invention has been made to solve the problem as described above, and has an object to obtain an elevator information providing device that enables a user of the elevator information providing device to examine the specification of an elevator on the basis of a standard model.

### Solution to Problem

An elevator information providing device according to the present invention includes: to acquire data of a building, and to infer a standard model of an elevator from the data of the building using a trained model for inferring the standard model of the elevator suitable for installation in the building from the data of the building and output data of the inferred standard model of the elevator, wherein the data of the building includes data as to whether or not the building is for rent, and in a case where the building is for rent, the processing circuitry infers the standard model of the elevator having a capacity larger than a capacity of an elevator in a case where the building is not for rent.

### Advantageous Effects of Invention

With an elevator information providing device according to the present invention, a user of the elevator information providing device can examine the specification of an elevator on the basis of a standard model. This is because an inference unit infers a standard model of an elevator from data of the building, and outputs data of the inferred standard model of the elevator.

### BRIEF DESCRIPTION OF DRAWINGS

FIG. 1 is a diagram for explaining an application example of an elevator information providing device according to a first embodiment of the present invention.

FIG. 2 is a configuration diagram of the elevator information providing device according to the first embodiment of the present invention.

FIG. 3 is an example of a cross-sectional view of an elevator as viewed from above.

FIG. 4 is a flowchart showing an elevator information providing method using the elevator information providing device according to the first embodiment of the present invention.

FIG. 5 is a configuration diagram of a learning device that generates a trained model to be used by the elevator information providing device according to the first embodiment of the present invention.

FIG. 6 is a flowchart regarding a learning sequence to be performed by the learning device that generates the trained model to be used by the elevator information providing device according to the first embodiment of the present invention.

FIG. 7 is a diagram for explaining an example of a learning method to be implemented by the learning device that generates the trained model to be used by the elevator information providing device according to the first embodiment of the present invention.

FIG. 8 is a configuration diagram of an elevator information providing device according to a second embodiment of the present invention.

FIG. 9 is a configuration diagram of a learning device that generates a trained model to be used by the elevator information providing device according to the second embodiment of the present invention.

FIG. 10 is a configuration diagram of an elevator information providing device according to a third embodiment of the present invention.

FIG. 11 is a configuration diagram of an elevator information providing device according to a fourth embodiment of the present invention.

### DESCRIPTION OF EMBODIMENTS

### First Embodiment

First, an application example of an elevator information providing device 100 according to a first embodiment of the present invention is described. The elevator information providing device 100 according to the present embodiment is based on the assumption that the user is an architectural designer, but the user is not limited to this and may be any person who considers purchasing or ordering an elevator. Note that, in a case where the user is simply mentioned in the following description, the user means a person who considers purchasing or ordering an elevator and is the user of the elevator information providing device 100, and a user of the elevator is called a passenger.

The elevator information providing device 100 according to the present embodiment forms part of a WEB site that provides elevator information. That is, the user of the elevator information providing device 100 is a user of a WEB site created by the elevator information providing device 100. The WEB site created by the elevator information providing device 100 provides elevator information when data of a building in which an elevator is to be installed or data of required specifications for the elevator is input by the user.

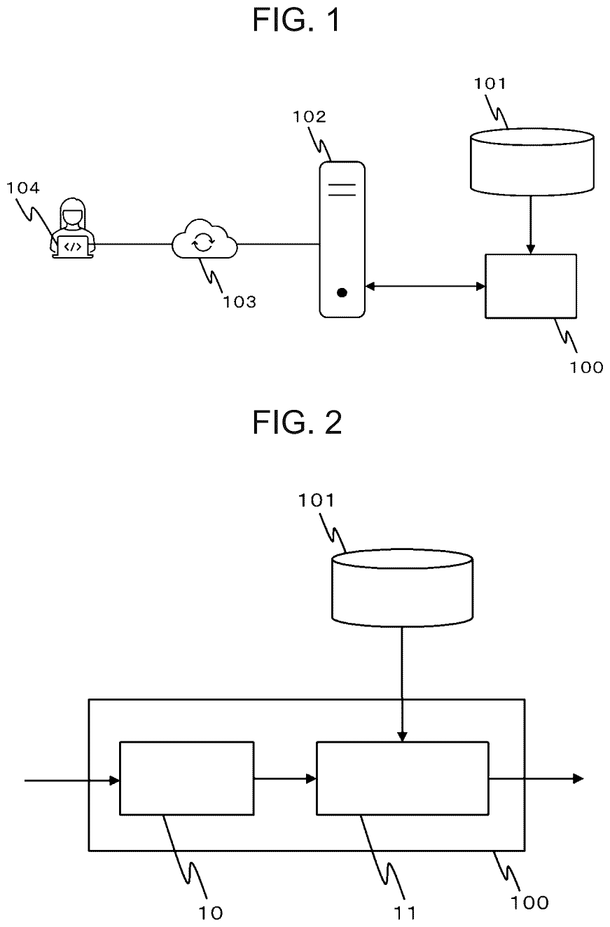

FIG. 1 is a diagram for explaining an application example of the elevator information providing device 100 according to the first embodiment of the present invention. The elevator information providing device 100 according to the present embodiment provides the user with elevator information via a server 102 and an Internet line 103. FIG. 1 is explained in line with the flow of data. As illustrated in FIG. 1, the user's personal computer 104 is connected to the server 102 via the Internet line 103. Building data the user has input to the personal computer 104 is input to the elevator information providing device 100 through the server 102. The elevator information providing device 100 infers a standard model of an elevator from the data of the building input through the server 102 using a trained model stored in a trained model storing device 101 and outputs data of the inferred standard model of the elevator.

The data output from the elevator information providing device 100 is input to the personal computer 104 of the user through the server 102, and the standard model of the elevator is displayed on the personal computer 104. That is, the WEB site created by the elevator information providing device 100 is a WEB site that shows the standard model of the elevator when the data of the building is input by the user, and recommends the standard model of the elevator suitable for installation in the building when the data of the building is input by the user.

As described above, when the user of the elevator information providing device 100 inputs data of the building to the personal computer 104, the standard model of the elevator is displayed on the personal computer 104, so that the user starts examining the specification of the elevator on the basis of the displayed standard model of the elevator.

Next, the configuration of the elevator information providing device 100 according to the first embodiment of the present invention is described. FIG. 2 is a configuration diagram of the elevator information providing device 100 according to the first embodiment of the present invention. As illustrated in FIG. 2, the elevator information providing device 100 according to the present embodiment includes: a building data acquiring unit 10 that acquires data of a building; and an inference unit 11 that infers a standard model of an elevator from the data of the building input from the building data acquiring unit 10 using a trained model for inferring the standard model of the elevator suitable for installation in the building from the data of the building and output data of the inferred standard model of the elevator. The trained model is stored in the trained model storing device 101.

The building data acquiring unit 10 acquires, through the server 102, the data of the building the user of the elevator information providing device 100 has input to the user's personal computer 104. For example, in a case where the user is an architectural designer who is going to build a building, the user inputs data of the building to be built, to the personal computer 104. The data of the to-be-built building that has been input to the personal computer 104 is acquired by the building data acquiring unit 10 of the elevator information providing device 100 through the server 102.

The data of the building includes data of the region in which the building is to be built, data of the type of the building, data of the number of floors of the building, data of the number of persons who will use the elevator, data of the size of the building, and data as to whether or not it is necessary to take measures for welfare in the building, for example. The WEB site created by the elevator information providing device 100 has items to which the region in which the building is to be built, the type of the building, the number of floors of the building, the number of persons who will use the elevator, the size of the building, whether or not welfare measures are necessary in the building, and the like are input, and the building data acquiring unit 10 acquires the data input to these items.

The inference unit 11 infers the standard model of the elevator from the data of the building input from the building data acquiring unit 10 using the trained model stored in the trained model storing device 101 and outputs data of the inferred standard model of the elevator. The data of the standard model of the elevator output from the inference unit 11 is input to the personal computer 104 of the user, and the standard model of the elevator is displayed on the personal computer 104.

Note that the elevator information providing device 100 is formed with a central processing unit (CPU), for example, but is not limited thereto. The trained model storing device 101 is formed with a semiconductor memory such as a flash memory, a read only memory (ROM), or a random access memory (RAM), or a hard disk drive (HDD), but is not limited thereto.

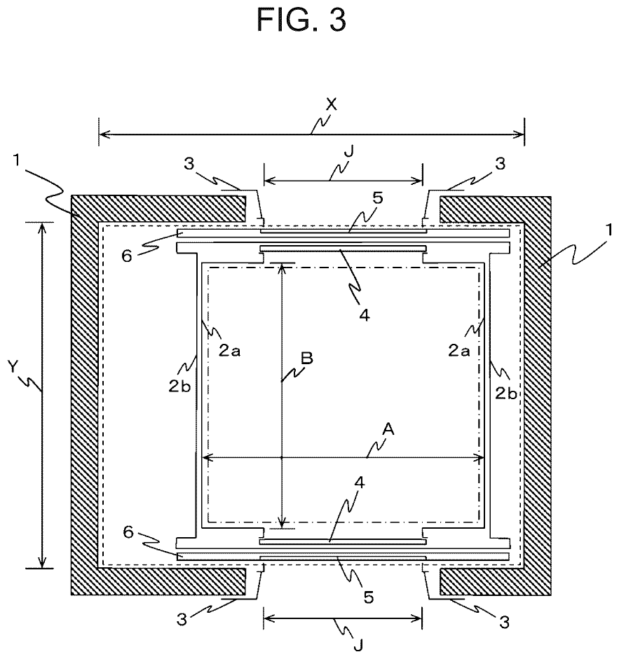

Next, the standard model of the elevator to be inferred by the inference unit 11 of the elevator information providing device 100 according to the present embodiment is described with reference to FIG. 3. FIG. 3 is an example of a cross-sectional view of the elevator as viewed from above, and is a diagram generally called a hoistway plan view. The elevator includes a car, and moves up and down in the hoistway. A hoistway member 1 forms the hoistway and a doorway opening. The hoistway member 1 is formed separately from the structure of the building, and has a height corresponding to the number of levels in the building. The hoistway is a space formed by the hoistway member 1, and is the space surrounded by a dotted line in FIG. 3. The doorway opening is an opening formed by the hoistway member 1, and part of the elevator hall is formed in the doorway opening. A user of the elevator gets on and off the elevator from the elevator hall formed with an elevator hall member 3.

The elevator car includes an inner wall 2a and an outer wall 2b. The elevator illustrated in FIG. 3 includes two car doors 4, two hall doors 5, and two hall door pockets 6. The hall doors 5 open and close by sliding in the hall door pockets 6. The car doors 4 open and close by sliding between the inner wall 2a and the outer wall 2b. The inner wall 2a of the car forms a car space and a car opening. The car space is the space in which a passenger stays after getting on the elevator, and is the space surrounded by a dot-and-dash line in FIG. 3. The car doors 4 are installed at the ends of the car opening.

The elevator illustrated in FIG. 3 has two doorways, but there are elevators each having one doorway. In the present embodiment, the elevator is not limited to one having two doorways, and may have one doorway. An elevator with one doorway includes a car door 4, a hall door 5, and a hall door pocket 6. In the hoistway plane, the inner wall 2a of the car is divided into two in the case of an elevator with two doorways, but the inner wall 2a of the car is integrally formed as a single wall in the case of an elevator with a single doorway. Also, in the hoistway plane, the hoistway member 1 is divided into two in the case of an elevator with two doorways, but the hoistway member 1 is integrally formed as a single member in the case of an elevator with a single doorway. The designs of the other members are changed as appropriate, depending on the number of doorways of the elevator.

As shown in FIG. 3, the internal dimension of the hoistway is represented by X×Y, and the internal dimension of the car is represented by A×B. The width allowed for a user of the elevator to pass through is shown as the width J of the doorways of the car. In the hoistway plane, X represents a distance in the hoistway within the distance between inner walls of the hoistway member 1, and is a distance in a direction parallel to the doorway width J of the car. In the hoistway plane, Y represents a distance in the hoistway within the distance between inner walls of the hoistway member 1, and is a distance in a direction perpendicular to the doorway width J of the car. That is, X and Y are orthogonal to each other. In the hoistway plane, A represents a distance in the car space within the distance between inner walls 2a of the car, and is a distance in a direction parallel to the doorway width J of the car. In the hoistway plane, B represents a distance in the car space within the distance between inner walls 2a of the car, and is a distance in a direction perpendicular to the doorway width J of the car. That is, A and B are orthogonal to each other.

In the present embodiment, the standard model of the elevator is a model with a lineup in which the internal dimensions A×B of the car, the widths J of the doorway of the car, and the load capacities are the same, but the other specifications vary. That is, if the elevator illustrated in FIG. 3 is of the standard model, there are models whose internal dimension A×B of the car, width J of the doorway of the car, and load capacity are the same as those of the elevator illustrated in FIG. 3, but the other specifications thereof are different from those of the elevator illustrated in FIG. 3. For example, if there are elevators whose internal dimensions A×B of the car, widths J of the doorway of the car, and load capacities are the same as those of the elevator illustrated in FIG. 3, but whose conveyance speeds are different from that of the elevator illustrated in FIG. 3, those are standard models of elevators.

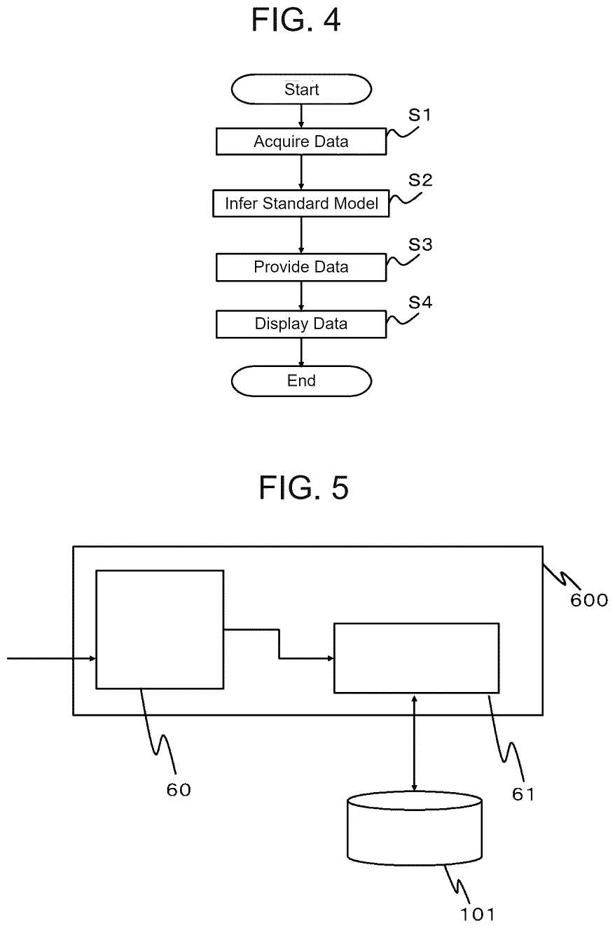

Next, an elevator information providing method using the elevator information providing device 100 according to the present embodiment is described. FIG. 4 is a flowchart showing an elevator information providing method using the elevator information providing device 100 according to the first embodiment of the present invention. As shown in FIG. 4, the elevator information providing method using the elevator information providing device 100 includes: an acquisition step S1 of acquiring data of the building; an inference step S2 of inferring the standard model of an elevator from the data of the building acquired in the acquisition step S1, and outputting the data; a provision step S3 of providing the user with the output data of the standard model of the elevator; and a display step S4 of displaying the provided data of the standard model of the elevator on the personal computer 104 of the user.

The acquisition step S1 is a step of acquiring data of the building. In the acquisition step S1, the building data acquiring unit 10 acquires, through the server 102, the data of the building that has been input to the personal computer 104 by the user of the elevator information providing device 100. The building data acquiring unit 10 then outputs the acquired data of the building to the inference unit 11. After completion of the acquisition step S1, the elevator information providing method using the elevator information providing device 100 in the present embodiment proceeds to the inference step S2.

The inference step S2 is a step of inferring the standard model of the elevator from the data of the building acquired in the acquisition step S1 by using a trained model for inferring the standard model of an elevator suitable for installation in the building from the data of the building, and outputting the inferred data of the standard model of the elevator. In the inference step S2, the inference unit 11 first acquires the trained model from the trained model storing device 101. The data of the building that has been output from the building data acquiring unit 10 is then input to the trained model acquired by the inference unit 11, and the inference unit 11 infers the standard model of the elevator suitable for installation in the building. After inferring the standard model of the elevator, the inference unit 11 outputs the data to the server 102. After completion of the inference step S2, the elevator information providing method using the elevator information providing device 100 in the present embodiment proceeds to the provision step S3.

The provision step S3 is a step of providing the user with the data of the standard model of the elevator, which has been output from the inference unit 11. In the provision step S3, the server 102 provides, via the Internet line 103, the user with the data of the standard model of the elevator, which has been output by the inference unit 11. That is, in the provision step S3, the data of the standard model of the elevator, which has been output from the elevator information providing device 100, is provided to the user via the server 102 and the Internet line 103. After completion of the provision step S3, the elevator information providing method using the elevator information providing device 100 in the present embodiment proceeds to the display step S4.

The display step S4 is a step of displaying the provided data of the standard model of the elevator on the personal computer 104 of the user. In the display step S4, the personal computer 104 of the user displays the data of the standard model of the elevator, which has been provided from the server 102 via the Internet line 103. In the present embodiment, the method for displaying the data of the standard model of the elevator is not limited to any particular method. An external view of the standard model of the elevator may be displayed, or the product number of the standard model of the elevator may be displayed, for example. It is sufficient that the display is made in such a manner that the user can understand which elevator is to be considered for installation.

As the standard model of the elevator is displayed on the personal computer 104, the user can start examining the specification of the elevator on the basis of the displayed standard model of the elevator. Although the process described below continues thereafter in the display step S4 in the elevator information providing method using the elevator information providing device 100 in the present embodiment, it is not limited thereto, and the display step S4 may be completed at this point.

When the personal computer 104 displays the data of the standard model of the elevator in the display step S4, the user selects the data on the personal computer 104. As the user selects the standard model of the elevator displayed on the personal computer 104, the data of the specification of the standard model of the elevator is displayed on the personal computer 104. That is, when the user selects the standard model of the elevator displayed on the WEB site, the data of the specification of the standard model of the elevator is reflected in the content of the specification items of the elevator on the WEB site. Thus, the user can easily customize the elevator specification based on the standard model of the elevator, and easily start the examination when examining the specification of the elevator on the basis of the standard model of the elevator. After completion of the display step S4, the elevator information providing method using the elevator information providing device 100 in the present embodiment comes to an end.

In the present embodiment, the inference unit 11 may infer one standard model or two or more standard models of elevators in the inference step S2. In a case where one standard model of the elevator is to be inferred by the inference unit 11 in the inference step S2, the inference unit 11 infers the standard model of the elevator most suitable for installation in the building. In a case where two or more standard models of elevators are to be inferred by the inference unit 11 in the inference step S2, the inference unit 11 may infer the standard models of elevators in order of recommendation for installation in the building, or without any order of recommendation. In a case where an inference has been made with order of recommendation given to standard models of elevators suitable for installation in the building, the inference unit 11 outputs data of the standard models of elevators together with the order of recommendation. In a case where an inference has been made without order of recommendation given to standard models of elevators suitable for installation in the building, only the data of the two or more standard models of elevators is output.

In the present embodiment, the method for displaying the data of the standard model of the elevator to be displayed on the personal computer 104 is not limited to any particular method. Therefore, in a case where the inference unit 11 makes an inference by giving order of recommendation to two or more types of standard models of elevators suitable for installation in the building, for example, the display method may be devised as appropriate by displaying a standard model that is higher in the order of recommendation larger than a standard model that is lower in the order of recommendation, or displaying an external view of a standard model that is higher in the order of recommendation while displaying the product number of a standard model that is lower in the order of recommendation. Other than that, in a case where the inference unit 11 makes an inference without giving order of recommendation to two or more types of standard models of elevators suitable for installation in the building, their external views may be displayed side by side thereof in the same size so that the user can easily select the elevator to be considered for reference.

Next, a learning device 600 that generates a trained model to be used by the elevator information providing device 100 according to the present embodiment is described. FIG. 5 is a configuration diagram of the learning device 600 that generates a trained model to be used by the elevator information providing device 100 according to the first embodiment of the present invention. As illustrated in FIG. 5, the learning device 600 includes a training data acquiring unit 60 and a model generating unit 61. The training data acquiring unit 60 acquires training data including data of a building and data of the specification of an elevator suitable for installation in the building. Using the training data, the model generating unit 61 generates a trained model for inferring the standard model of the elevator from the data of the building.

Note that the learning device 600 is formed with a CPU, for example, but is not limited thereto.

The training data acquiring unit 60 acquires training data including data of the building and data of the specification of an elevator suitable for installation in the building. The training data is input to the training data acquiring unit 60 by a manufacturer that manufactures the elevator, a manufacturer that sells the elevator, or the like. The training data is data in which the data of the building and the data of the specification of the elevator suitable for installation in the building are associated with each other.

The model generating unit 61 learns the standard model of the elevator in accordance with the training data created on the basis of the combination of the data of the building and the data of the specification of the elevator suitable for installation in the building output from the training data acquiring unit 60. That is, the trained model for inferring an optimum standard model of an elevator from the data of the building and the data of the specification of the elevator suitable for installation in the building is generated.

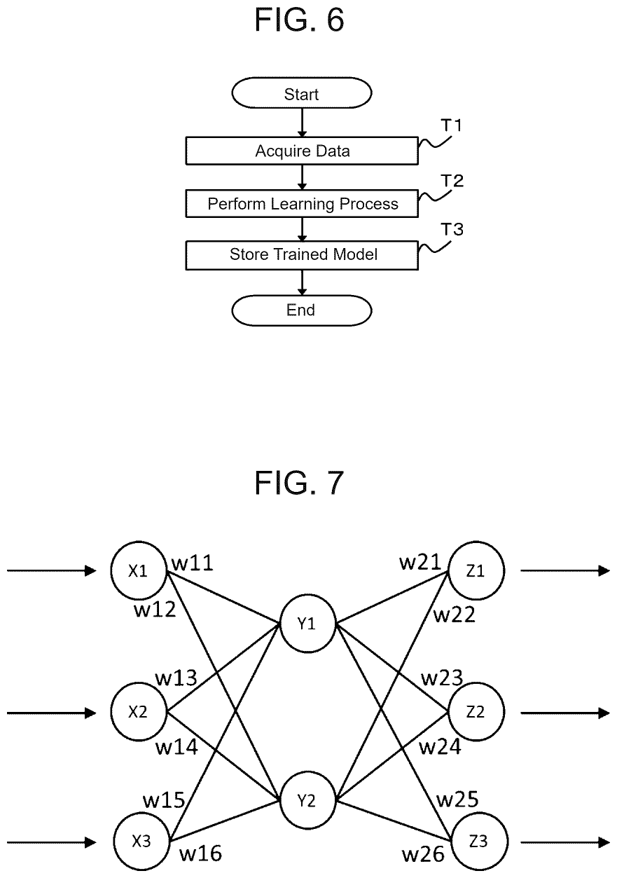

Next, a learning sequence to be performed by the learning device 600 that generates the trained model to be used by the elevator information providing device 100 according to the present embodiment is described. FIG. 6 is a flowchart showing the learning sequence to be performed by the learning device 600 that generates the trained model to be used by the elevator information providing device 100 according to the first embodiment of the present invention. As shown in FIG. 6, the learning device 600 includes a first learning step T1 of acquiring data, a second learning step T2 of performing a learning process, and a third learning step T3 of storing a trained model.

The first learning step T1 is a step of acquiring data of the building and data of the specification of an elevator suitable for installation in the building. In the first learning step T1, the training data acquiring unit 60 acquires the data of the building and the data of the specification of the elevator suitable for installation in the building. Note that the training data acquiring unit 60 may simultaneously acquire the data of the building and the data of the specification of the elevator suitable for installation in the building, or may acquire the data of the building and the data of the specification of the elevator suitable for installation in the building at different timings. It is sufficient that the training data acquiring unit 60 can acquire the data of the building associated with the data of the specification of the elevator suitable for installation in the building. In the present embodiment, after completion of the first learning step T1, the learning sequence being performed by the learning device 600 that generates the trained model to be used by the elevator information providing device 100 proceeds to the second learning step T2.

The second learning step T2 is a step of generating the trained model in accordance with the training data created on the basis of the combination of the data of the building and the data of the specification of the elevator suitable for installation in the building acquired in the first learning step T1. In the second learning step T2, the model generating unit 61 first learns the standard model of the elevator in accordance with the training data created on the basis of the combination of the data of the building and the data of the specification of the elevator suitable for installation in the building output from the training data acquiring unit 60. The model generating unit 61 then generates the trained model. That is, the model generating unit 61 learns the standard model of the elevator by so-called supervised learning, and generates the trained model. After completion of the second learning step T2, the learning sequence being performed by the learning device 600 that generates the trained model to be used by the elevator information providing device 100 in the present embodiment proceeds to the third learning step T3.

The third learning step T3 is a step of storing the trained model generated in the second learning step T2. In the third learning step T3, the trained model storing device 101 stores the trained model generated by the model generating unit 61 in the second learning step T2. After completion of the third learning step T3, the learning sequence being performed by the learning device 600 that generates the trained model to be used by the elevator information providing device 100 in the present embodiment comes to an end.

FIG. 7 is a diagram for explaining an example of a learning method to be implemented by the learning device 600 that generates the trained model to be used by the elevator information providing device 100 according to the first embodiment of the present invention. As the learning algorithm to be used by the model generating unit 61, a known algorithm such as supervised learning, unsupervised learning, or reinforcement learning can be used. As an example, a case where a neural network is adopted is described.

The model generating unit 61 learns the standard model of the elevator by so-called supervised learning, in accordance with a neural network model, for example. Here, supervised learning refers to a technique of giving a set of data of an input and a result (label) to a learning device to learn features in the training data and infer a result from an input. The neural network includes an input layer formed with a plurality of neurons, an intermediate layer (a hidden layer) formed with a plurality of neurons, and an output layer formed with a plurality of neurons. The intermediate layer may be formed with a single layer, or may be formed with two or more layers.

In the case of a three-layer neural network as illustrated in FIG. 7, when a plurality of inputs is input to the input layer (X1-X3), the value is multiplied by a weight W1 (w11-w16) and is input to the intermediate layer (Y1-Y2), and the result is further multiplied by a weight W2 (w21-w26) and is output from the output layer (Z1-Z3). This output result varies depending on the values of the weight W1 and the weight W2.

In the present embodiment, the neural network learns the standard model of the elevator by so-called supervised learning, in accordance with the training data created on the basis of the combination of the data of the building and the data of the specification of the elevator suitable for installation in the building acquired by the training data acquiring unit 60. That is, the neural network performs learning by adjusting the weight W1 and the weight W2 in such a manner that the result output from the output layer by inputting the data of the building to the input layer approaches the data of the specification of the elevator suitable for installation in the building.

The model generating unit 61 generates and outputs the trained model by performing learning as described above. The output trained model is stored into the trained model storing device 101.

Next, specific examples of the training data necessary for the model generating unit 61 to learn to generate the trained model to be used by the elevator information providing device 100 according to the present embodiment are described. In the present embodiment, a plurality of pieces of training data is acquired by the training data acquiring unit 60. The training data is a set of input data and result (label) data, and examples thereof are described one by one below.

As a specific example, the training data acquiring unit 60 acquires data of a region in which the building is to be built, and data of the specification of an elevator conforming to the law in the region. The data of the region in which the building is to be built is acquired as the data of the building, and the data of the specification of an elevator conforming to the law in the region is acquired as the data of the specification of an elevator suitable for installation in the building. The data of the region in which the building is to be built and the data of the specification of an elevator conforming to the law in the region, which are associated with each other, are acquired, and are used by the model generating unit 61 to learn the standard model of the elevator.

The data of the region in which the building is to be built includes a plurality of pieces of data, and the training data acquiring unit 60 acquires the data of the specification of an elevator conforming to the law in each region. The data of the region in which the building is to be built includes the name of the prefecture and the name of the municipality, for example, but the present embodiment is not limited thereto. In a case where the elevator information providing device 100 according to the present embodiment is used outside Japan, the method of dividing regions is changed as appropriate to a manner of dividing local governments in the country. Further, the law of the region is ordinances in the region, for example.

As another example, the training data acquiring unit 60 acquires data of the region in which the building is to be built, and data of the specification of an elevator used in the past in the region. The data of the region in which the building is to be built is acquired as the data of the building, and the data of the specification of an elevator used in the past in the region is acquired as the data of the specification of an elevator suitable for installation in the building. The data of the region in which the building is to be built and the data of the specification of an elevator used in the past in the region, which are associated with each other, are acquired, and are used by the model generating unit 61 to learn the standard model of the elevator. Note that the data of the region in which the building is to be built includes a plurality of pieces of data, and the training data acquiring unit 60 acquires the data of the specification of an elevator used in the past in each region. The data of the region in which the building is to be built includes the name of the prefecture and the name of the municipality, for example, but the present embodiment is not limited thereto as described above.

As another example, the training data acquiring unit 60 acquires data of the type of the building and data of the specification of an elevator suitable for the type of the building. The data of the type of the building is acquired as the data of the building, and the data of the specification of an elevator suitable for the type of the building is acquired as the data of the specification of an elevator suitable for installation in the building. The data of the type of the building and the data of the specification of an elevator suitable for the type of the building, which are associated with each other, are acquired, and are used by the model generating unit 61 to learn the standard model of the elevator. The data of the type of building is the name of the purpose of use of the building, and is an office, a residence, a hospital, a school, or the like.

As another example, the training data acquiring unit 60 acquires data of the type of the building, and data of the specification of an elevator that has been used for the type in the past. The data of the type of the building is acquired as the data of the building, and the data of the specification of an elevator that has been used for the type in the past is acquired as the data of the specification of an elevator suitable for installation in the building. The data of the type of the building and the data of the specification of an elevator that has been used for the type in the past, which are associated with each other, are acquired, and are used by the model generating unit 61 to learn the standard model of the elevator.

As another example, the training data acquiring unit 60 acquires data of the number of floors of the building and data of the specification of an elevator that satisfies the speed necessary for the building. The data of the number of floors of the building is acquired as the data of the building, and the data of the specification of an elevator that satisfies the speed necessary for the building is acquired as the data of the specification of an elevator suitable for installation in the building. The data of the number of floors of the building and the data of the specification of an elevator that satisfies the speed necessary for the building, which are associated with each other, are acquired, and are used by the model generating unit 61 to learn the standard model of the elevator. Note that the required elevator speed is normally higher in a building having a larger number of floors than in a building having a smaller number of floors.

As another example, the training data acquiring unit 60 acquires data of the number of persons who will use the elevator and data of the specification of an elevator that satisfies the necessary capacity. The data of the number of persons who will use the elevator is acquired as the data of the building, and the data of the specification of an elevator that satisfies the necessary capacity is acquired as the data of the specification of an elevator suitable for installation in the building. The data of the number of persons who will use the elevator and the data of the specification of an elevator that satisfies the necessary capacity, which are associated with each other, are acquired, and are used by the model generating unit 61 to learn the standard model of the elevator.

The data of the number of persons who will use the elevator may be one piece of numerical data such as data of an estimated resident population of the entire building, or may include two or more pieces of numerical data. For example, the data of the number of persons who will use the elevator may be formed with data of the population of the building excluding a reference floor and data of the population of the reference floor of the building. In the present embodiment, the reference floor is the floor with the front doorway to the building, and is the floor with the entrance. The input items in the WEB site created by the elevator information providing device 100 include items for inputting the population of the building excluding the reference floor and the population of the reference floor of the building so that the building data acquiring unit 10 acquires the data of the number of persons who will use the elevator. The learning by the model generating unit 61 is performed so as to generate a trained model capable of inferring the standard model of an elevator from the data input by the user to the items to which the population of the building excluding the reference floor and the population of the reference floor of the building are input.

In this example, in a case where the data of the number of persons who will use the elevator includes two or more pieces of numerical data, the data is formed with the data of the population of the building excluding the reference floor and the data of the population of the reference floor of the building, for example, but it is not limited thereto. For example, the data of the number of persons who will use the elevator may be formed with data of an estimated resident population per floor and data of the number of floors of the building.

In addition to the above, the data of the number of persons who will use the elevator may be associated with data of the number of elevators to be installed and data of the elevator size as desired by the user of the elevator information providing device 100. This is because items for inputting the desired number of elevators to be installed and the desired elevator size are included in the input items in the WEB site created by the elevator information providing device 100. When acquiring the data of the number of persons who will use the elevator and the data of the specification of an elevator satisfying the necessary capacity, which are associated with each other, the training data acquiring unit 60 acquires data obtained by combining the data of the number of elevators to be installed and the data of the desired elevator size as desired by the user of the elevator information providing device 100, which are associated with the data of the number of persons who will use the elevator. That is, the model generating unit 61 may perform learning, using training data in which data that is associated with the data obtained by combining the data of the number of elevators to be installed and the data of the desired elevator size as desired by the user of the elevator information providing device 100, and is the data of the number of persons who will use the elevator is combined as a set with the data of the specification of an elevator that satisfies the necessary capacity.

As another example, the training data acquiring unit 60 acquires data as to whether or not the building needs welfare measures, data of the specification of an elevator whose doorway width of the car is a width great enough for a wheelchair to pass through, and data of the specification of an elevator whose internal dimension of the car is an internal dimension large enough to accommodate a wheelchair. The data as to whether or not the building needs welfare measures is acquired as the data of the building, and the data of the specification of an elevator whose doorway width of the car is a width great enough for a wheelchair to pass through and the data of the specification of an elevator whose internal dimension of the car is an internal dimension large enough to accommodate a wheelchair are acquired as the data of the specification of an elevator suitable for installation in the building. The data as to whether or not the building needs welfare measures is associated with the data of the specification of an elevator whose doorway width of the car is a width great enough for a wheelchair to pass through and the data of the specification of an elevator whose internal dimension of the car is an internal dimension large enough to accommodate a wheelchair, and is acquired, and the associated pieces of data are used by the model generating unit 61 to learn the standard model of the elevator. At this point of time, in a case where the building needs welfare measures, the model generating unit 61 performs learning so as to output the standard model of an elevator whose doorway width of the car is a width great enough for a wheelchair to pass through, and whose internal dimension of the car is an internal dimension large enough to accommodate a wheelchair.

The input items in the WEB site created by the elevator information providing device 100 include an item for inputting whether or not the building needs welfare measures so that the building data acquiring unit 10 acquires the data as to whether or not the building needs welfare measures. The learning by the model generating unit 61 is performed so as to generate a trained model capable of inferring the standard model of an elevator from the data input by the user to the item to which the data as to whether or not the building needs welfare measures is input. The item to which the data as to whether or not the building needs welfare measures may be an item that directly asks whether or not the building needs welfare measures, or may be an item that indirectly asks whether or not the building needs welfare measures, such as whether or not the building to which the barrier-free law is applied.

As another example, the training data acquiring unit 60 acquires data of the type of the building, data of the specification of an elevator whose doorway width of the car is a width great enough for a wheelchair to pass through, and data of the specification of an elevator whose internal dimension of the car is an internal dimension large enough to accommodate a wheelchair. The data of the type of the building is acquired as the data of the building, and the data of the specification of an elevator whose doorway width of the car is a width great enough for a wheelchair to pass through and the data of the specification of an elevator whose internal dimension of the car is an internal dimension large enough to accommodate a wheelchair are acquired as the data of the specification of an elevator suitable for installation in the building. The data of the type of the building is associated with the data of the specification of an elevator whose doorway width of the car is a width great enough for a wheelchair to pass through and the data of the specification of an elevator whose internal dimension of the car is an internal dimension large enough to accommodate a wheelchair, and is acquired, and the associated pieces of data are used by the model generating unit 61 to learn the standard model of the elevator. Depending on the type of the building, welfare measures are necessary in the building, and therefore, this learning is performed. This is because, in a case where the type of the building is a hospital, for example, welfare measures are necessary in the building.

In this example, the model generating unit 61 performs learning using training data in which the data of the type of the building is combined as a set with the data of the specification of an elevator whose doorway width of the car is a width great enough for a wheelchair to pass through and the data of the specification of an elevator whose internal dimension of the car is an internal dimension large enough to accommodate a wheelchair, but it is not limited thereto. The model generating unit 61 may associate the data of the type of the building with the data as to whether or not the building needs welfare measures, for example, and perform learning using training data in which the data that is associated with the data of the type of the building and is the data as to whether or not the building needs welfare measures is combined as a set with the data of the specification of an elevator whose doorway width of the car is a width great enough for a wheelchair to pass through and the data of the specification of an elevator whose internal dimension of the car is an internal dimension large enough to accommodate a wheelchair.

As another example, the training data acquiring unit 60 acquires data of the size of the building, data of the specification of an elevator whose doorway width of the car is a width great enough for a wheelchair to pass through, and data of the specification of an elevator whose internal dimension of the car is an internal dimension large enough to accommodate a wheelchair. The data of the size of the building is acquired as the data of the building, and the data of the specification of an elevator whose doorway width of the car is a width great enough for a wheelchair to pass through and the data of the specification of an elevator whose internal dimension of the car is an internal dimension large enough to accommodate a wheelchair are acquired as the data of the specification of an elevator suitable for installation in the building. The data of the size of the building is associated with the data of the specification of an elevator whose doorway width of the car is a width great enough for a wheelchair to pass through and the data of the specification of an elevator whose internal dimension of the car is an internal dimension large enough to accommodate a wheelchair, and is acquired, and the associated pieces of data are used by the model generating unit 61 to learn the standard model of the elevator. In a case where the size of the building is large, welfare measures are necessary in the building, and therefore, this learning is performed. The size of the building is the total floor area, for example, but may be a combination of the number of floors of the building and the area of one floor.

In this example, the model generating unit 61 performs learning using training data in which the data of the size of the building is combined as a set with the data of the specification of an elevator whose doorway width of the car is a width great enough for a wheelchair to pass through and the data of the specification of an elevator whose internal dimension of the car is an internal dimension large enough to accommodate a wheelchair, but it is not limited thereto. The model generating unit 61 may associate the data of the size of the building with the data as to whether or not the building needs welfare measures, for example, and perform learning using training data in which the data that is associated with the data of the size of the building and is the data as to whether or not the building needs welfare measures is combined as a set with the data of the specification of an elevator whose doorway width of the car is a width great enough for a wheelchair to pass through and the data of the specification of an elevator whose internal dimension of the car is an internal dimension large enough to accommodate a wheelchair.

As another example, the training data acquiring unit 60 acquires data as to whether the building is a building for rent, and data of the specification of an elevator that satisfies the necessary capacity. The data as to whether the building is a building for rent is acquired as the data of the building, and the data of the specification of an elevator that satisfies the necessary capacity is acquired as the data of the specification of an elevator suitable for installation in the building. The data as to whether the building is a building for rent and the data of the specification of an elevator that satisfies the necessary capacity, which are associated with each other, are acquired, and are used by the model generating unit 61 to learn the standard model of the elevator.

At this point of time, in a case where the building is a building for rent, the model generating unit 61 performs learning so as to output the standard model of an elevator with a larger capacity than in a case where the building is not a building for rent. That is, in a case where the building is a building for rent, the model generating unit 61 generates a trained model so that the inference unit 11 infers the standard model of an elevator with a larger capacity than in a case where the building is not a building for rent.

The data as to whether the building is a building for rent is data associated with the data of the type of the building. That is, the training data acquiring unit 60 acquires data in which the data that is associated with the data of the type of the building and is the data as to whether the building is a building for rent is combined as a set with the data of the specification of an elevator that satisfies the necessary capacity. Note that a building for rent is a building that is rented as an office or a store in exchange for a rental payment, and, in the present embodiment, even if the rental target is an entire building or only one floor, the building is regarded as a building for rent.

Note that, in the present embodiment, in a case where the standard model of an elevator is to be learned with the data of the specification of an elevator used in the past, the model generating unit 61 may perform learning so that the standard model of the elevator is higher in the order of recommendation.

As described above, with the elevator information providing device 100 according to the present embodiment, the user of the elevator information providing device 100 can examine the specification of an elevator on the basis of a standard model. This is because the inference unit 11 infers a standard model of an elevator from the data of the building, and outputs data of the inferred standard model of the elevator.

If the user of the elevator information providing device 100 according to the present embodiment can examine the specification of an elevator on the basis of the standard model, the manufacturer that manufactures the elevator can reduce the load during the manufacturing process. This is because the standard model can prevent generation of new work, since the manufacturing process has already been set. The load during the manufacturing process can also be lowered in a case where the user of the elevator information providing device 100 considers a special model. This is because the load on the manufacturer during the process of manufacturing the elevator is lower in a case where the special model is considered as a design change based on the standard model than in a case where the special model is considered from the beginning.

Also, the elevator information providing device 100 according to the present embodiment uses a trained model for inferring a standard model of an elevator suitable for installation in the building from the data of the building, to perform work that is performed by the manufacturer who manufactures the elevator, a sales representative of the manufacturer who sells the elevator, or the like in conventional cases. Conventionally, it has been difficult for a sales representative of the manufacturer to guide a person who is considering purchasing or ordering an elevator to examine the specification of the elevator on the basis of the standard model, depending on the sales representative of the manufacturer. On the other hand, the elevator information providing device 100 according to the present embodiment uses a trained model for inferring a standard model of an elevator suitable for installation in the building from data of the building, and thus, can perform the work at any time. That is, with the elevator information providing device 100 according to the present embodiment, the elevator information to be provided to the person who is considering purchasing or ordering an elevator can be prevented from varying depending on the manufacturer who manufactures the elevator or the sales representative of the manufacturer who sells the elevator.

Further, the user of the elevator information providing device 100 according to the present embodiment does not need to select an elevator while checking the law in the region in which the building is to be built, and thus, can easily perform the elevator selection work. This is because the trained model to be used by the elevator information providing device 100 according to the present embodiment is generated by acquiring the data of the region in which the building is to be built and the data of the specification of an elevator conforming to the law in the region, which are associated with each other, and the elevator information providing device 100 according to the present embodiment outputs the data of the standard model of an elevator conforming to the law in the region in which the building is to be built.

Further, the user of the elevator information providing device 100 according to the present embodiment can select an elevator preferred in the region in which the building is to be built. This is because the trained model to be used by the elevator information providing device 100 according to the present embodiment is generated by acquiring the data of the region in which the building is to be built and the data of the specification of an elevator used in the past in the region, which are associated with each other, and the elevator information providing device 100 according to the present embodiment outputs the data of the standard model of an elevator used in the past in the region in which the building is to be built.

Furthermore, the user of the elevator information providing device 100 according to the present embodiment does not need to select an elevator, taking the type of building into consideration. Depending on the type of building, the user needs to select an elevator while checking various laws, and it is a burden on the user to select an elevator while taking the type of the building into consideration. On the other hand, the user of the elevator information providing device 100 according to the present embodiment does not need to select an elevator while taking the type of the building into consideration, and thus, can easily perform the elevator selection work. This is because the trained model to be used by the elevator information providing device 100 according to the present embodiment is generated by acquiring the data of the type of the building and the data of the specification of an elevator suitable for the type, which are associated with each other, and the elevator information providing device 100 according to the present embodiment outputs the data of the standard model of an elevator suitable for the type.

Further, the user of the elevator information providing device 100 according to the present embodiment can select an elevator preferred for each type of building. This is because the trained model to be used by the elevator information providing device 100 according to the present embodiment is generated by acquiring the data of the type of the building and the data of the specification of an elevator that is of the type and has been used in the past, which are associated with each other, and the elevator information providing device 100 according to the present embodiment outputs the data of the standard model of an elevator that is of the type and has been used in the past.

Although a case where supervised learning is applied to the learning algorithm that is used by the model generating unit 61 has been described in the present embodiment, it is not limited thereto. As the learning algorithm, reinforcement learning, unsupervised learning, semi-supervised learning, or the like can be adopted, other than supervised learning.

Note that, in the present embodiment, the elevator information providing device 100 and the learning device 600 may be incorporated into the server 102.

Further, the elevator information providing device 100 may be used directly by the user, without the server 102 and the Internet line 103. Also, the elevator information providing device 100 may be connected to the server 102 via an Internet line. Applications of the elevator information providing device 100 according to the present embodiment may be changed as appropriate within the scope of the present invention.

Note that, in the present embodiment, the type of the Internet line 103 is not limited to any particular type. Also, the server 102 may be a physical server, or may be a cloud server.

### Second Embodiment

The configuration of an elevator information providing device 200 according to a second embodiment of the present invention is described. The elevator information providing device 200 according to the second embodiment of the present invention has the same application examples as those of the elevator information providing device 100 according to the first embodiment of the present invention, except for including an inference unit 21, instead of the inference unit 11 of the elevator information providing device 100 according to the first embodiment of the present invention. In the second embodiment of the present invention, only the differences from the first embodiment of the present invention are described, and explanation of aspects similar to those of the first embodiment of the present invention is not made herein.

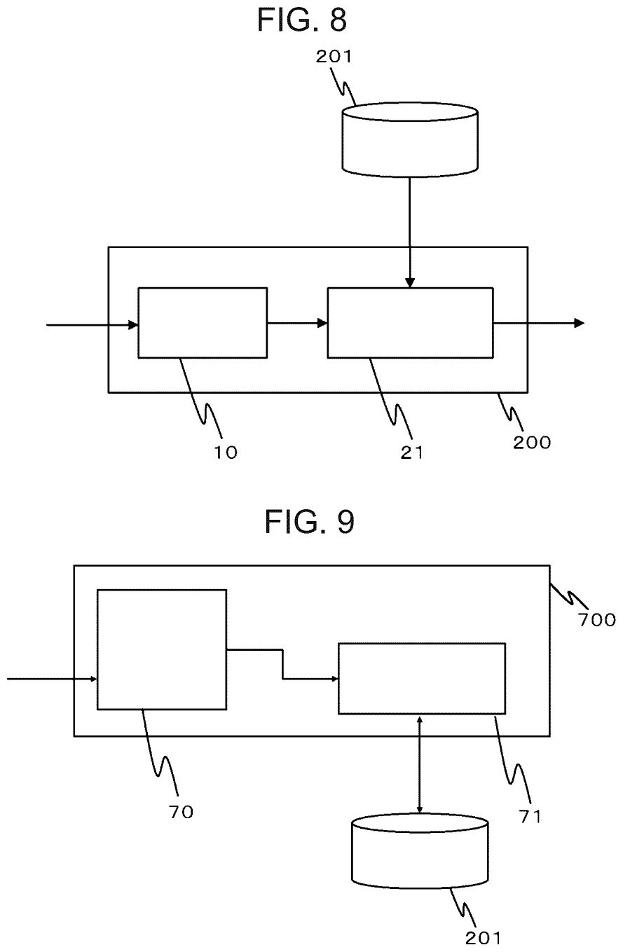

FIG. 8 is a configuration diagram of the elevator information providing device 200 according to the second embodiment of the present invention. As illustrated in FIG. 8, the elevator information providing device 200 according to the present embodiment includes: a building data acquiring unit 10 that acquires data of the building; and an inference unit 21 that infers a standard model of elevators and the number thereof from the data of the building input from the building data acquiring unit, using a trained model for inferring a standard model of elevators suitable for installation in the building from the data of the building, and output data of the inferred standard model of elevators and the number thereof. The trained model is stored in a trained model storing device 201.

The inference unit 21 infers a standard model of elevators suitable for installation in the building and the number thereof from the data of the building input from the building data acquiring unit 10, using the trained model stored in the trained model storing device 201, and outputs data of the inferred standard model of elevators and the number thereof. The data of the standard model of elevators and the number thereof that have been output from the inference unit 21 are input to a personal computer 104 of the user, and is displayed on the personal computer 104.

Unlike that of the first embodiment of the present invention, the inference unit 21 of the elevator information providing device 200 according to the present embodiment infers not only the standard model of elevators suitable for installation in the building but also the number thereof from the data of the building input from the building data acquiring unit 10, using the trained model stored in the trained model storing device 201. Therefore, the trained model stored in the trained model storing device 201 is different between the present embodiment and the first embodiment of the present invention.

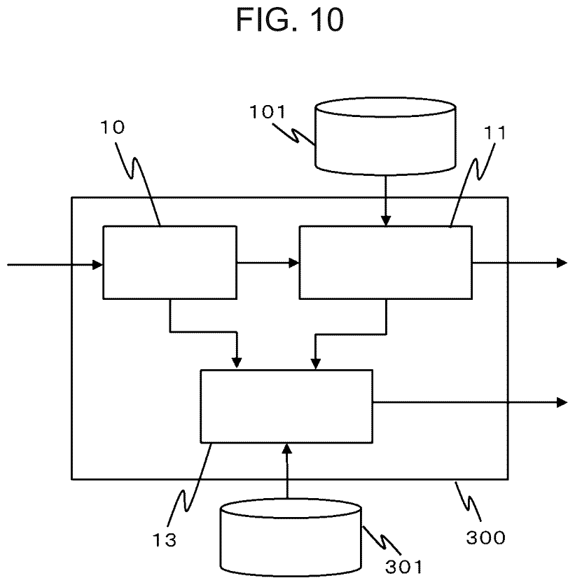

Next, a learning device 700 that generates a trained model to be used by the elevator information providing device 200 according to the present embodiment is described. FIG. 9 is a configuration diagram of the learning device 700 that generates a trained model to be used by the elevator information providing device 200 according to the second embodiment of the present invention. As illustrated in FIG. 9, the learning device 700 includes: a training data acquiring unit 70 that acquires training data; and a model generating unit 71 that generates a trained model for inferring a standard model of elevators from the data of the building, using the training data.

Next, specific examples of the training data necessary for the model generating unit 71 to learn to generate the trained model to be used by the elevator information providing device 200 according to the present embodiment are described. In the present embodiment, a plurality of pieces of training data is acquired by the training data acquiring unit 70. The training data acquiring unit 70 acquires data to be described below, in addition to the data acquired by the training data acquiring unit 60 of the learning device 600 that generates the trained model to be used by the elevator information providing device 100 according to the first embodiment of the present invention. The training data is a set of input data and result (label) data, and specific examples of the data to be acquired by the training data acquiring unit 70 in addition to the training data acquiring unit 60 are described one by one below.

As one specific example, the training data acquiring unit 70 acquires data of the number of floors of the building, data of the number of persons who will use elevators, and data of the carrying capacity of elevators. The carrying capacity of elevators is determined by a combination of the capacity of the elevators and the number of the elevators. The data of the number of floors of the building and the data of the number of persons who will use the elevators are acquired as the data of the building. The data of the number of floors of the building and the data of the number of persons who will use the elevators are associated with the data of the carrying capacity of the elevators and are acquired, and these pieces of data are used by the model generating unit 71 to learn the standard model of elevators and the number thereof.

As another example, the training data acquiring unit 70 acquires data as to whether or not the building a building for rent, and data of the carrying capacity of the elevators. The data as to whether or not the building is a building for rent is acquired as the data of the building. The data as to whether or not the building is a building for rent and the data of the carrying capacity of the elevators, which are associated with each other, are acquired, and are used by the model generating unit 71 to learn the standard model of the elevators and the number thereof. At this point of time, in a case where the building is a building for rent, the model generating unit 71 performs learning so as to output the standard model of the elevators and the number thereof, with a higher carrying capacity than in a case where the building is not a building for rent. That is, in a case where the building is a building for rent, the model generating unit 71 generates a trained model so that the inference unit 21 infers the standard model of the elevators with a higher carrying capacity than in a case where the building is not a building for rent, and the number thereof.

As described above, with the elevator information providing device 200 according to the present embodiment, the user of the elevator information providing device 200 can examine the specification of elevators on the basis of the standard model, taking into consideration the number of elevators to be installed in the building. This is because the inference unit 21 infers the standard model of the elevators and the number thereof from the data of the building, and outputs data of the inferred standard model of the elevators and the number thereof.

### Third Embodiment

The configuration of an elevator information providing device 300 according to a third embodiment of the present invention is described. The elevator information providing device 300 according to the third embodiment of the present invention has the same application examples as those of the elevator information providing devices according to the first embodiment of the present invention and the second embodiment of the present invention. In the third embodiment of the present invention, only the differences from the first embodiment of the present invention and the second embodiment of the present invention are described, and explanation of aspects similar to those of the first embodiment of the present invention and the second embodiment of the present invention is not made herein.

FIG. 10 is a configuration diagram of the elevator information providing device 300 according to the third embodiment of the present invention. As illustrated in FIG. 10, the elevator information providing device 300 according to the present embodiment includes: a building data acquiring unit 10 that acquires data of a building; and an inference unit 11 that infers a standard model of an elevator from the data of the building input from the building data acquiring unit 10 using a trained model for inferring the standard model of the elevator suitable for installation in the building from the data of the building and outputs data of the inferred standard model of the elevator. The trained model is stored in the trained model storing device 101.

The elevator information providing device 300 according to the present embodiment further includes a regulation acquiring unit 13 that acquires data of an article of a regulation related to installation of the standard model of the elevator from a plurality of regulations related to construction of a building using the data of the building input from the building data acquiring unit 10 and the data of the standard model of the elevator input from the inference unit 11 and outputs the acquired data of the article of the regulation. The plurality of regulations related to construction of a building is stored in a regulation storing device 301. The data of the article of the regulation output from the regulation acquiring unit 13 is provided to the user via the server 102 and the Internet line 103. The data of the article of the regulation acquired by the regulation acquiring unit 13 is then displayed on the personal computer 104 of the user.

Since the elevator information providing device 300 according to the present embodiment allows the user to examine the specification of an elevator on the basis of the standard model, and the inference unit 11 infers the standard model of the elevator, information about the elevator provided by the elevator information providing device 300 according to the present embodiment relates to the standard model. For the manufacturer who manufactures the elevator, a sales representative of the manufacturer who sells the elevator, and the like, it is possible to present the article of the regulation related to installation of the elevator to the user without causing the regulation acquiring unit 13 to perform a complicated process as long as the elevator is of the standard model, and the elevator information providing device 300 according to the present embodiment can achieve this.

The plurality of regulations related to construction of buildings include various local governments'ordinances, the Building Standards Act, the Order for Enforcement of the Building Standards Act, the Regulations for Enforcement of the Building Standards Act, the City Planning Act, the Construction Industry Act, the Licensed Architect Act, the Fire Service Act, the Act on Improvement of Energy Consumption Performance of Buildings, and the Act on Promotion of Movement of Elderly Persons and Persons with Disabilities, for example. The Act on Improvement of Energy Consumption Performance of Buildings is commonly called the Building Energy Saving Act. The Act on Promotion of Movement of Elderly Persons and Persons with Disabilities is commonly called the Barrier-Free Act. In the present embodiment, the article of the regulation related to installation of the standard model of the elevator acquired by the regulation acquiring unit 13 is an item of a regulation such as Article ○ of the Building Standards Act. Note that, in a case where the elevator information providing device 300 according to the present embodiment is used outside Japan, the plurality of regulations related to building construction may be changed as appropriate to related laws and regulations in the country.

In the present embodiment, the method and the timing of displaying the data of the article of the regulation to be displayed on the personal computer 104 are not limited to any particular ones. As for the display method, the words written in the article of the regulation may be displayed on the personal computer 104 as they are, a document in which the article of the regulation is written may be displayed in such a manner that the data can be downloaded, or a link leading to a WEB site in which the article of the regulation is written may be displayed, for example. As for the display timing, the data may be displayed on the personal computer 104 at the same time as the data of the standard model of the elevator, or the data of the standard model of the elevator may be displayed first, and then the data may be displayed on the personal computer 104 after the user completes all the examination of the specification of the elevator based on the standard model, for example.

As described above, with the elevator information providing device 300 according to the present embodiment, the user of the elevator information providing device 300 can examine the specification of an elevator on the basis of a standard model, and can also check the data of an article of a regulation related to installation of the standard model of the elevator. This is because the regulation acquiring unit 13 acquires the data of the article of the regulation related to installation of the standard model of the elevator from a plurality of regulations related to construction of a building using the data of the building input from the building data acquiring unit 10 and the data of the standard model of the elevator input from the inference unit 11 and outputs the acquired data of the article of the regulation.

### Fourth Embodiment

The configuration of an elevator information providing device 400 according to a fourth embodiment of the present invention is described. The elevator information providing device 400 according to the fourth embodiment of the present invention has the same application examples as those of the elevator information providing devices according to the first embodiment of the present invention to the third embodiment of the present invention. In the fourth embodiment of the present invention, only the differences from the first embodiment of the present invention to the third embodiment of the present invention are described, and explanation of aspects similar to those of the first embodiment of the present invention to the third embodiment of the present invention is not made herein.

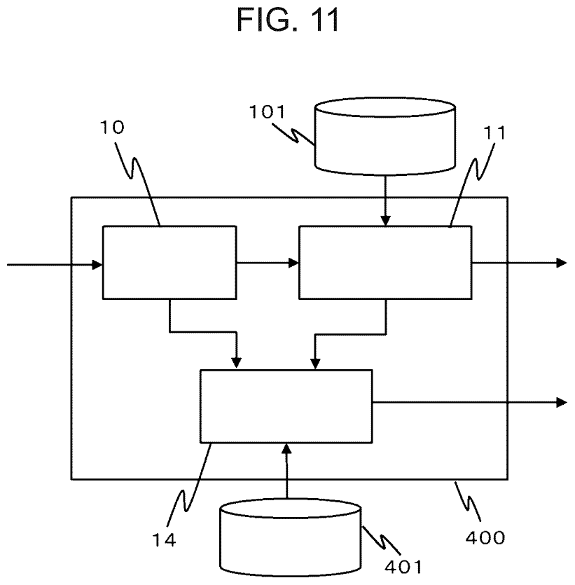

FIG. 11 is a configuration diagram of the elevator information providing device 400 according to the fourth embodiment of the present invention. As illustrated in FIG. 11, the elevator information providing device 400 according to the present embodiment includes: a building data acquiring unit 10 that acquires data of a building; and an inference unit 11 that infers a standard model of an elevator from the data of the building input from the building data acquiring unit 10 using a trained model for inferring the standard model of the elevator suitable for installation in the building from the data of the building and outputs data of the inferred standard model of the elevator. The trained model is stored in the trained model storing device 101.

The elevator information providing device 400 according to the present embodiment further includes a drawing acquiring unit 14 that acquires a drawing related to installation of the standard model of the elevator from a plurality of drawings related to installation of an elevator using the data of the building input from the building data acquiring unit 10 and the data of the standard model of the elevator input from the inference unit 11 and outputs the acquired drawing. The plurality of drawings related to the installation of an elevator is stored in a drawing storing device 401. The data of the drawing output from the drawing acquiring unit 14 is provided to the user via the server 102 and the Internet line 103. The data of the drawing acquired by the drawing acquiring unit 14 is then displayed on the personal computer 104 of the user.

Since the elevator information providing device 400 according to the present embodiment allows the user to examine the specification of an elevator on the basis of the standard model, and the inference unit 11 infers the standard model of the elevator, information about the elevator provided by the elevator information providing device 400 according to the present embodiment relates to the standard model. For the manufacturer who manufactures the elevator, a sales representative of the manufacturer who sells the elevator, and the like, it is possible to present the drawing related to installation of the elevator to the user without causing the drawing acquiring unit 14 to perform a complicated process as long as the elevator is of the standard model, and the elevator information providing device 400 according to the present embodiment can achieve this.

The plurality of drawings related to installation of an elevator include a drawing in which a plan view of the hoistway is drawn, a drawing in which a cross-sectional view of the hoistway is drawn, and a drawing in which an installation view is drawn, for example, include not only drawings created as two-dimensional CAD data but also drawings created as three-dimensional CAD data, and include not only still drawings but also dynamic drawings, for example.

In the present embodiment, the method and the timing of displaying the data of the drawing to be displayed on the personal computer 104 are not limited to any particular ones. As for the display method, the data of the drawing may be displayed on the personal computer 104 as it is, or a document of the data of the drawing may be displayed in such a manner that it can be downloaded, for example. As for the display timing, the data may be displayed on the personal computer 104 at the same time as the data of the standard model of the elevator, or the data of the standard model of the elevator may be displayed first, and then the data may be displayed on the personal computer 104 after the user completes all the examination of the specification of the elevator based on the standard model, for example.

As described above, with the elevator information providing device 400 according to the present embodiment, the user of the elevator information providing device 400 can examine the specification of an elevator on the basis of a standard model, and can also check the data of a drawing related to installation of the standard model of the elevator. This is because the drawing acquiring unit 14 acquires the data of the drawing related to installation of the standard model of the elevator from a plurality of drawings related to installation of an elevator using the data of the building input from the building data acquiring unit 10 and the data of the standard model of the elevator input from the inference unit 11 and outputs the acquired data of the drawing.

Note that, in the present invention, the embodiments and modifications can be freely combined with each other, and each of the embodiments can be modified or omitted as appropriate, within the scope of the present invention.

### REFERENCE SIGNS LIST

1: hoistway member, 2a: inner wall of the car, 2b: outer wall of the car, 3: elevator hall member, 4: car door, 5: hall door, 6: hall doorcase, 10: building data acquiring unit, 11, 21: inference unit, 13: regulation acquiring unit, 14: drawing acquiring unit, 60, 70: training data acquiring unit, 61, 71: model generating unit, 100, 200, 300, 400: elevator information providing device, 101, 201: trained model storing device, 102: server, 103: Internet line, 104: personal computer, 301: regulation storing device, 401: drawing storing device, 600, 700: learning device

1. An elevator information providing device comprising processing circuitry
to acquire data of a building, and
to infer a standard model of an elevator from the data of the building using a trained model for inferring the standard model of the elevator suitable for installation in the building from the data of the building and output data of the inferred standard model of the elevator,
wherein the data of the building includes data as to whether or not the building is for rent, and
in a case where the building is for rent, the processing circuitry infers the standard model of the elevator having a capacity larger than a capacity of an elevator in a case where the building is not for rent.

2. The elevator information providing device according to claim 1, wherein
the processing circuitry infers a number of elevators being the standard model from the data of the building, and outputs data of the inferred number of elevators being the standard model.

3. The elevator information providing device according to claim 1, wherein the processing circuitry is further configured
to acquire data of an article of a regulation related to the installation of the elevator of the standard model from a plurality of regulations related to construction of the building using the data of the building and the data of the standard model of the elevator and output the acquired data of the article of the regulation.

4. The elevator information providing device according to claim 1, wherein the processing circuitry is further configured
to acquire data of a drawing related to the installation of the elevator being the standard model from a plurality of drawings related to the installation of the elevator using the data of the building and the data of the standard model of the elevator and output the acquired data of the drawing.

5. The elevator information providing device according to claim 1, wherein
the data of the building includes data of a region in which the building is to be built, and
the processing circuitry infers the standard model of the elevator from data of a specification of an elevator conforming to a law in the region.

6. The elevator information providing device according to claim 1, wherein
the data of the building includes data of a region in which the building is to be built, and
the processing circuitry infers the standard model of the elevator from data of a specification of an elevator used in a past in the region.

7. The elevator information providing device according to claim 1, wherein
the data of the building includes data of a type of the building, and
the processing circuitry infers the standard model of the elevator from data of a specification of an elevator suitable for the type.

8. The elevator information providing device according to claim 1, wherein
the data of the building includes data of a type of the building, and
the processing circuitry infers the standard model of the elevator from data of a specification of an elevator used for the type in a past.

9. The elevator information providing device according to claim 1, wherein
the data of the building includes data as to whether or not the building needs a welfare measure, and,
in a case where a welfare measure is required for the building, the processing circuitry infers the standard model of the elevator whose doorway width of a car is great enough for a wheelchair to pass through, and whose internal dimension of the car is large enough to accommodate the wheelchair.

10. An elevator information providing method comprising:
performing acquisition of data of a building; and
performing inference of a standard model of an elevator from the data of the building acquired in the acquisition using a trained model for inferring the standard model of the elevator suitable for installation in the building from the data of the building and output data of the inferred standard model of the elevator,
wherein the data of the building includes data as to whether or not the building is for rent, and, in a case where the building is for rent, in the inference, the standard model of the elevator having a capacity larger than a capacity of an elevator is inferred in a case where the building is not for rent.

11. A learning device comprising processing circuitry
to acquire training data including data of a building and data of a specification of an elevator suitable for installation in the building, and
to generate a trained model for inferring the standard model of the elevator from the data of the building using the training data,
wherein the data of the building includes data as to whether or not the building is for rent, and,
in a case where the building is for rent, the processing circuitry infers the standard model of the elevator having a capacity larger than a capacity of an elevator in a case where the building is not for rent.
